(19) United States
(12) Patent Application Publication
(10) Pub. No.: US 2008/0069385 A1
(43) Pub. Date: Mar. 20, 2008

(54) Amplifier and Method of Amplification

(75) Inventor: Lawrence Jay Revit, Braintree, VT (US)

Correspondence Address: PATENT SUCCESS, INTELL. PROP. PROTECTION, LLC, 7 FIELD ROAD, WEST LEBANON, NH, 03784, US

(73) Assignee: Revitronix, Braintree, VT (US)

(21) Appl. No.: 11/857,337

(22) Filed: Sep. 18, 2007

Related U.S. Application Data
(60) Provisional application No. 60/826,069, filed on Sep. 18, 2006.

(51) Int. Cl. H04R 25/00; H03G 7/00

(52) U.S. Cl. 381/321; 381/106; 381/120

(57) ABSTRACT

A method of amplification includes amplifying an input signal with a predetermined or user adjustable maximum gain to produce a second signal and compressing the dynamic range of the second signal with an automatic gain control to produce an output signal. The compression ratio of the automatic gain control is greater than one for output signals below a predetermined threshold output signal level and is essentially one for output signals above the predetermined threshold output signal level. The compression ratio may be predetermined or the method may include determining the compression ratio of the automatic gain control. The compression ratio may be determined according to the amplitude of the output signal or according to an input-output curve. The input-output curve my be predetermined and may be selected according to the auditory needs of a listener. Preferably the input-output curve is determined according to the predetermined or user adjustable maximum gain.

### CROSS REFERENCE TO RELATED APPLICATIONS

The present application is a continuation-in-part of provisional U.S. patent application No. 60826069 filed on Sep. 18, 2006, which is herein incorporated by reference.

### BACKGROUND

The term “compression” refers to automatic gain control (AGC) that reduces the overall dynamic range of a signal. In other words, compression reduces the range between the softest and the loudest signals. Ideally, compression does nothing to the waveform of a signal; it acts only on the overall level (volume) of the signal. In general, there are two types of compression: upward compression, and downward compression. Upward (or low-level) compression raises the level of low-level inputs (automatically turns up the volume for soft sounds). Downward (or high-level) compression lowers the level of high-level signals (automatically turns down the volume for loud sounds). A compression device may be configured to provide either or both of these types of compression.

The term “compression ratio” quantifies the rate of compression. A specified change in input level results in a unit change in output level. For example, with a compression ratio of 2:1, for every 2-dB change in the input, a 1-dB change occurs in the output; the dynamic range is compressed two-to-one (output versus input).

The term “threshold” or “kneepoint” is the level below which upward compression occurs or above which downward compression occurs. Thresholds or kneepoints may be specified in terms of either input levels or output levels.

The term “diffuse-field referred” means that specifications are given as if the output of the device were being monitored in a diffuse sound field near the listener. A diffuse sound field is one for which the intensity of the field is independent of direction; the sound intensity from every direction is the same. An ideal diffuse field might be created at the center of a spherical, anechoic space having an infinite number of sound sources along the inner surface of the sphere. A practical example of a diffuse field would be a hard-walled reverberation chamber that has a sufficient number of sound sources and diffusing devices to create a very even distribution of reflections from all surfaces. The frequency response and dB SPL data in the following discussion and examples may be diffuse-field referred. Why use a “diffuse-field reference”? In everyday life, most listening environments—in rooms, that is—are somewhat, if not highly diffuse. Most of the sound one hears in rooms, even when listening to a talker just a few feet away, is reflected more-or-less randomly by the surfaces of the room. Thus, most sounds of everyday life are from multiple directions. There may not be a need to favor the sound from one direction or another in specifying remedial amplification for overcoming hearing difficulties. Using a diffuse sound-field reference in design and evaluation of sound systems using earphones may eliminate bias toward any particular direction of propagation, and therefore leads to the most natural-sounding tonal balance possible.

The discovery of the natural compression amplifier of the cochlea (inner ear) dates back to the late 1940s, when Gold (1948) controversially, but correctly, observed that the known capabilities of the human auditory system exceeded those that could be explained by passive mechanisms alone. Although his mentor, von Békésy, had earlier observed and described the passive mechanical properties of the basilar membrane (a principle structure within the cochlea) that, in cadaver ears, accounted “partly” for the frequency resolution exhibited by the inner ear, it was Gold who saw that there must be an additional, active physiological mechanism, as yet undiscovered, required to accomplish the exquisite sensitivity and frequency selectivity exhibited by the normal human auditory system.

Jump thirty years ahead to 1978 when Kemp (1978) identified “a new auditory phenomenon” in the form of evoked otoacoustic emissions (EOAEs). When presented with an impulse signal via the ear canal, the normal inner ear echoed more energy back into the ear canal than was put in, more than what could be attributed to passive reflections. The mechanism was still not known, but the presence of an active, non-linear component in the cochlea was now evident. The outer hair cells (OHCs) were thought to play an important role (see FIG. 1), because, absent the OHCs, the EOAEs disappeared as well—accompanied by a moderate hearing loss.

In 1982, Neely and Kim (1983), proposed an “active cochlear model” after analyzing measurements of the motion of the cochlear partition (the basilar membrane and associated anatomical components that separate the electrolytic fluid spaces in the cochlea), measurements which were made in vivo in cats (Khana and Leonard, 1982) and guinea pigs (Sellick, Patuzzi, and Johnstone, 1982). Unlike in the human cadaver ears of von Békésy's studies decades earlier, in the living cochlea the motion of the cochlear partition itself could account for 100% of the very high sensitivity and sharp tuning previously observed both in auditory psychophysical experiments and in recordings made from auditory nerve fibers. Neely and Kim speculated that “an active mechanical behavior of the OHCs” could provide the “negative damping” required for the observed sensitivity and tuning of the motion of the cochlear partition.

Meanwhile, Davis (1982) coined the term “cochlear amplifier” in proposing a dual (active/passive) model for cochlear mechanics. The inner hair cells (IHCs), which have 95% of the synapses with ascending auditory nerve fibers in the cochlea, were the transducers, linearly converting acoustical inputs into nerve impulse patterns. The OHCs, three times more numerous than the IHCs, yet with only scant innervation, were somehow essential for the non-linear behavior of the cochlear amplifier, whose compression action increased the level of response to soft sounds, allowing them to be heard even when they originated at an intensity far less than the threshold of response of the IHCs.

Powerful as the total picture was becoming, the above evidence and speculation about a cochlear compression amplifier was based on consequential observation and deduction. Yet just around the corner was to come a momentous discovery by Brownell (1983), a discovery which was to lead to the answer to the question, “What is the mechanism of the cochlear amplifier?” Brownell was able to isolate OHCs in vivo for study. He applied transcellular alternating current and observed that the OHCs increased and decreased in length, in synchronism with the applied current. Ultimately, the OHCs were indeed shown to be the movers and shakers of the inner ear. Brownell commented, further, that “the microarchitecture of the organ of Corti (the main structure within the cochlear partition) permits length changes of OHCs in a manner that could significantly influence the mechanics of the cochlear partition and thereby contribute to the exquisite sensitivity of mammalian hearing.” At last, 35 years after Gold's hypothesis, the mechanism of the cochlear amplifier was known.

Separately, Killion (1979) had observed that people with mild-to-moderate hearing impairments seemed to hear quite normally when the sound level was loud enough. He designed the K-AMP™ high-fidelity hearing aid amplifier to provide gain with gentle compression for low input levels (upward, low-level, input-referred compression) while becoming acoustically transparent (zero gain and no compression) for high input levels. Although presumably based largely on observations of people with hearing loss, rather than on knowledge of the underlying cause of the pathology, the K-AMP served a prosthetic need, enhancing or replacing a damaged or absent OHC cochlear amplifier. Soft sounds reaching a hearing aid microphone were amplified using a 2:1 compression ratio, but once the input reached 90 dB SPL, gain dropped to unity and compression disappeared. This action is somewhat similar to that of the natural cochlear amplifier, which was discovered later and whose compressive action also seems to disappear for inputs of 90 dB SPL and above.

Somewhat later, Killion and Fikret-Pasa (1993) identified types of hearing loss not optimally matched to the processing provided by the K-AMP amplifier. When the hearing loss is substantial (i.e., greater than 60 dB), unity gain for loud sounds is insufficient for optimal intelligibility of those loud sounds. Not only is residual gain required for loud sounds with severe hearing impairment, but optimum speech intelligibility occurs when the signal level is almost uncomfortably loud—suggesting that output-limiting compression (compression ratios ˜10:1 or higher) could be employed with the required gain to maintain the required, nearly-uncomfortable loudness without causing amplifier saturation or exceeding a “loud but okay” listening level.

In addition to physiological hearing loss being the cause of impaired cochlear function, impaired cochlear function can be caused by adverse external listening conditions. For example, the hearing-research literature cites many examples where hearing loss is simulated using normal-hearing subjects with adverse listening conditions, such as by reducing the bandwidth of the presented sounds, or by adding background noise to the presented sounds, thereby reducing the signal-to-noise ratio of the presented sounds.

U.S. Pat. No. 4,170,720 discloses a high fidelity hearing aid for providing high quality sound and is primarily directed to those users whose hearing loss is such that they need some amplification for low level input signals, but do not need amplification for high level input signals. The apparatus has a logarithmic relationship over a selected intermediate input signal levels and a deviation toward linear operation at higher input signal levels.

U.S. Pat. No. 5,144,675 discloses a hearing aid amplifier wherein a gain control voltage is applied to a control terminal of a variable gain hearing aid amplifier which is logarithmically related to a signal voltage level which is sensed at either an input terminal or an output terminal of the amplifier and which is below a certain threshold value.

U.S. Pat. No. 6,628,795 discloses an automatic gain control in a hearing aid which is effected by detecting an input sound level and/or an output sound level and adapting the output sound level supplied by the hearing aid in response to the detected sound level by controlling the gain of the hearing aid towards an actual desired value of the output sound level. The gain control is effected at increases and decreases, respectively, of the input sound level by adjusting the gain towards the actual desired value with an attack time and a release time, respectively, which are adjusted in response to the detected sound level to a relatively short duration providing fast gain adjustment at high input and/or output sound levels and to a relatively long duration providing slow gain adjustment at low input and/or output sound levels.

U.S. Pat. No. 6,049,618 discloses a hearing aid which has input AGC and output AGC using only one attack/release circuit and only one variable gain amplifier. An input AGC signal and an output AGC signal are summed and the summed signal, processed through the attack/release circuit, is used to control the gain of the variable gain amplifier.

### BRIEF SUMMARY OF THE INVENTION

A method of amplification includes amplifying an input signal with a predetermined or user adjustable maximum gain to produce a second signal and compressing the dynamic range of the second signal with an automatic gain control to produce an output signal. The compression ratio of the automatic gain control is greater than one for output signals below a predetermined threshold output signal level and is essentially one for output signals above the predetermined threshold output signal level. The compression ratio is predetermined or the method may include determining the compression ratio of the automatic gain control. The compression ratio may be determined according to the amplitude of the output signal. Alternatively the compression ratio may be determined by an input-output curve. The input-output curve may be predetermined and may be selected according to the auditory needs of a listener. Preferably the input-output curve is determined according to the predetermined or user adjustable maximum gain. The compression ratio, the predetermined threshold output level, and/or the predetermined or user adjustable maximum gain may also be selected according to the auditory needs of a listener. The predetermined threshold output signal may be 90 dB SPL. The compression ratio may vary according to frequency, and may increase or decrease as frequency increases.

The method may further include altering the compression ratio below one or more sub-thresholds or above a maximum threshold or eliminating noise. The input signal may be divided into low- mid- and/or high-frequency band channels and the amplified band signals may be recombined into a single broadband channel. The method may also include adjustments to frequency response such as fine-tuning frequency response, compensating for deficiencies in frequency response of an output device, achieving a diffuse-field equivalent response, and/or correcting the frequency response of the output signal to achieve a diffuse-field equivalent response. The method may also include assuring safe listening levels, assuring comfortable listening levels, and/or assuring output does not exceed a maximum normal operating level.

An apparatus comprises a band amplifier comprising a predetermined or user adjustable gain, an input and an output, a band compressor in communication with the output of the band amplifier, and a level detector comprising an input in communication with the output of the band compressor and further comprising an output in communication with the band compressor. The band compressor has a compression ratio greater than one for output signals below a predetermined threshold output level and is essentially one for output signals above the predetermined threshold output level. The compression ratio, the predetermined threshold output level, and/or a gain of the band amplifier may be selected according to the auditory needs of a listener.

The apparatus may further comprise a signal source, a band filter, a signal combining device, an equalization filter, an output-limiting compression amplifier and/or an output device. The signal source may be a microphone, a telephone line, a storage device, or a wireless receiver. The storage device may be a record, a compact disk, an audio tape, a video tape, a digital video disk, a computer hard drive, a flash memory, or a read-only memory. The band filter may be a low pass, high pass, or band pass filter. The equalization filter may fine-tune frequency response, compensate for deficiencies in frequency response of an output device, or achieve a diffuse field reference. The output device may be an earphone, a telephone receiver, a hearing aid receiver, or a speaker. The output device may correct the frequency response of the output signal to achieve a diffuse-field equivalent response. The output-limiting compressor may assure that the output does not exceed safe listening levels, comfortable listening levels, and/or maximum operating levels.

The apparatus may include one or more additional amplifiers, each amplifier comprising a band amplifier comprising an input and an output, a band compressor connected to the output of the band amplifier, and a level detector comprising an input in communication with the output of the band compressor and further comprising an output in communication with the band compressor. The band compressor has a compression ratio greater than one below a predetermined threshold output level and essentially one above the predetermined threshold output level. The apparatus may include multiple band filters wherein slopes and off-band characteristics of the band filters are such that, once the bands have been amplified by differing amounts, the bands will recombine into a single signal whose frequency response is free from anomalous shapes and discontinuities.

### BRIEF DESCRIPTION OF THE DRAWINGS

FIG. 1 is a flowchart of a method of amplification

FIG. 2 is a flowchart of a method of amplification further including the step determining the compression ratio of the automatic gain control.

FIG. 3 is a flowchart of a method of amplification including the steps dividing an input signal into low- mid- and/or high-frequency band channels, recombining amplified band signals into a single broadband channel, and correcting the frequency response of the output signal to achieve a diffuse-field equivalent response.

FIG. 4 is a block diagram of an apparatus for amplification.

FIG. 5 is a block diagram of an apparatus for amplification having a multiple frequency bands.

FIG. 6 is a block diagram of an apparatus for amplification having a multiple equalization filters.

FIG. 7 is a compressive input/output curve.

FIG. 8 is an example of Normal low and high frequency input-output curves, appropriate for relatively flat hearing losses.

FIG. 9 is an example of Treble low and high frequency input-output curves, appropriate for sloping hearing losses.

FIG. 10 is a plot of output versus frequency response for the extremes of the Normal tone range.

FIG. 11 is a plot of output versus frequency response for the extremes of the Treble tone range.

FIG. 12 is a plot of gain versus frequency response for the extremes of the Normal tone range.

FIG. 13 is a plot of gain versus frequency response for the extremes of the Treble tone range.

### DETAILED DESCRIPTION OF INVENTION AND THE PREFERRED EMBODIMENT

The following detailed description of the invention and the preferred embodiment, in which like parts are labeled with like numerals, and the accompanying figures are intended to illustrate certain embodiments of the present invention and not to limit its scope in any way.

The present invention relates to an amplification method intended to help people hear better in adverse listening conditions. Adverse listening conditions may consist of the presence of environmental interference such as background noise, listening through a bandwidth-limited device such as a telephone line, a listener having a physiological hearing impairment, or a combination of these or other conditions. Specifically, the amplification method may provide an external prosthesis that alters sonic input to the auditory system in such a way that compensates for impaired cochlear (inner-ear) function, whether such impairment is caused by physiological or external conditions. In essence, the amplification method delivers to the ear the sound characteristics that allow for the best possible function of the auditory system under a wide range of conditions.

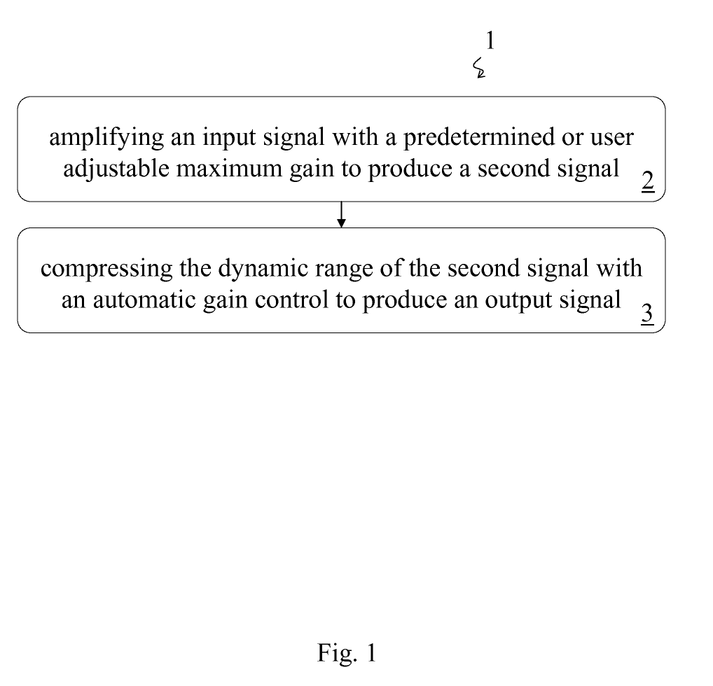

FIG. 1 is a flowchart of a method 1 of amplification. The method includes amplifying 2 an input signal with a predetermined or user adjustable maximum gain to produce a second signal and compressing 3 the dynamic range of the second signal with an automatic gain control to produce an output signal. The compression ratio of the automatic gain control is greater than one for output signals below a predetermined threshold output signal level and is essentially one for output signals above the predetermined threshold output signal level. The compression ratio may vary according to frequency and may increase or decrease as frequency increases. This allows for different levels of compression for different frequencies. For example, a listener may need compression of high-frequency sounds but no compression for low-frequency sound. The compression ratio may also be altered above a maximum threshold. For example, the compression ratio may be much greater than one above a maximum threshold, which may provide output limiting capability and may assure safe and/or comfortable listening levels. The compression ratio may also be altered below one or more sub-thresholds. For example, a noise gate or a compression ratio less than one may be included below a threshold to lessen undesirable noise which might otherwise be amplified.

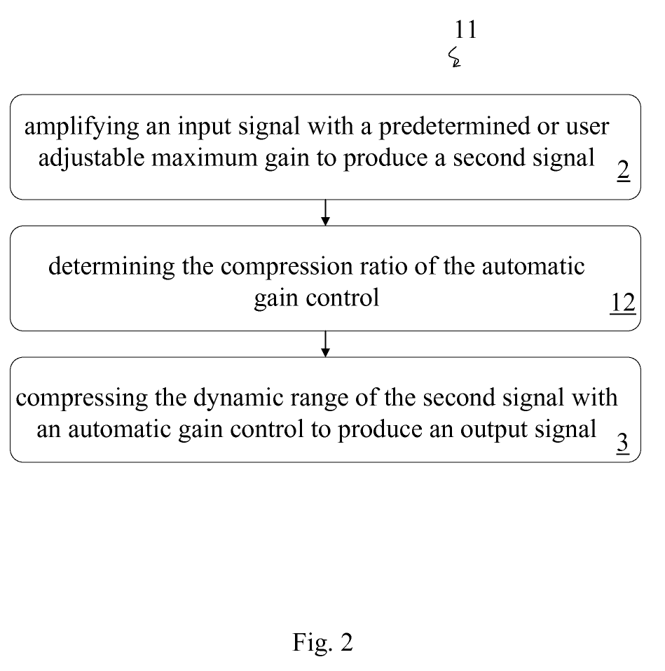

FIG. 2 is a flowchart of a method 11 of amplification further including the step determining 12 the compression ratio of the automatic gain control. The compression ratio may be determined according to the amplitude of the output signal or according to an input-output curve. The input-output curve may be predetermined or may be determined according to the predetermined or user adjustable maximum gain. Preferably, a family of input-output curves is generated having a compression ratio greater than one for output signals below a predetermined threshold output signal level and is essentially one for output signals above the predetermined threshold output signal level. One of the input-output curves is then selected which has the predetermined or user adjustable maximum gain, and a device such as a digital signal processor may then follow the input-output curve. The predetermined threshold output signal level may typically be 90 dB SPL.

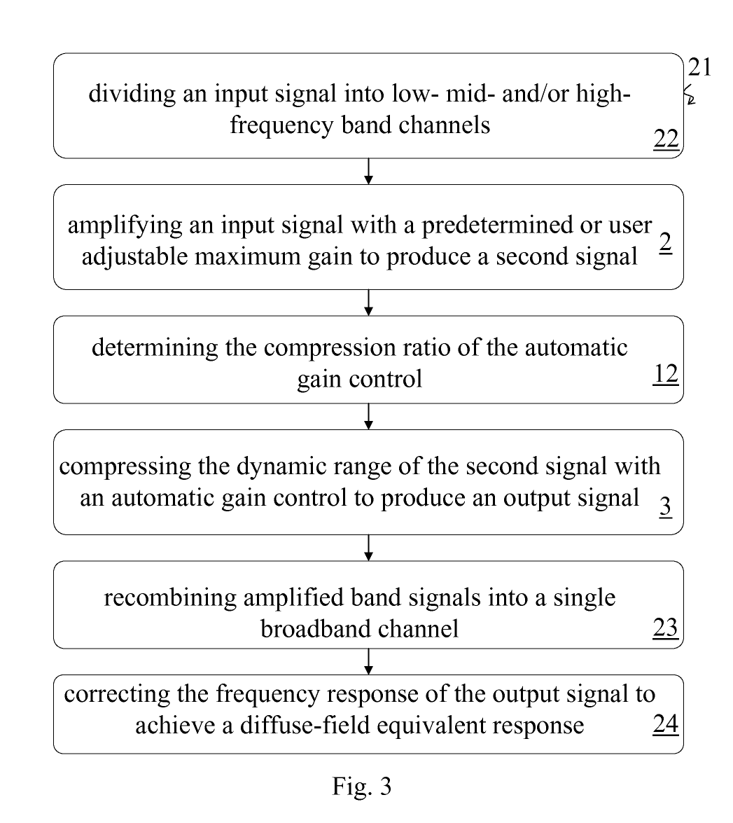

FIG. 3 is a flowchart of the preferred embodiment of a method 21 of amplification. The method further includes the steps dividing 22 an input signal into low- mid- and/or high-frequency band channels, recombining 23 amplified band signals into a single broadband channel. This may be desirable so that different frequency bands may have different characteristics according to the auditory needs of a listener. For example, a listener may need more amplification for high-frequency signals. Thus the input signal may be divided into high- and low-frequency bands, each with a different predetermined or user adjustable maximum gain. An input-output curve may be determined for each band and a device such as a digital signal processor may then follow the input-output curve for each band. The bands may then be recombined into a single broadband channel. The method further includes the step correcting 24 the frequency response of the output signal to achieve a diffuse-field equivalent response. This may be correct for deficiencies in an output device.

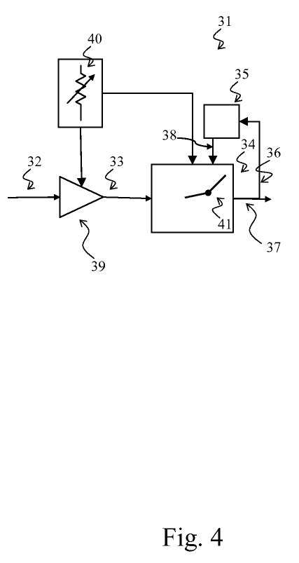

FIG. 4 is a block diagram of an apparatus 31 for amplification comprising a band amplifier 39, a band compressor 34, and a level detector 35. The amplifier 39 has an input 32 and an output 33 and the band compressor 34 is in communication with the output 33 of the band amplifier 39. The level detector 35 has an input 36 in communication with an output 37 of the band compressor and an output 38 in communication with the band compressor 34. The band compressor 34 has a compression ratio greater than one for output signals below a predetermined threshold 41 output level and is essentially one for output signals above the predetermined threshold 41 output level. The band amplifier 39 may have a predetermined or user adjusted gain control 40. The predetermined or user adjusted gain control 40 may be in communication with the band compressor 34. Setting of the predetermined or user adjusted gain control 40 may select a predetermined input-output curve.

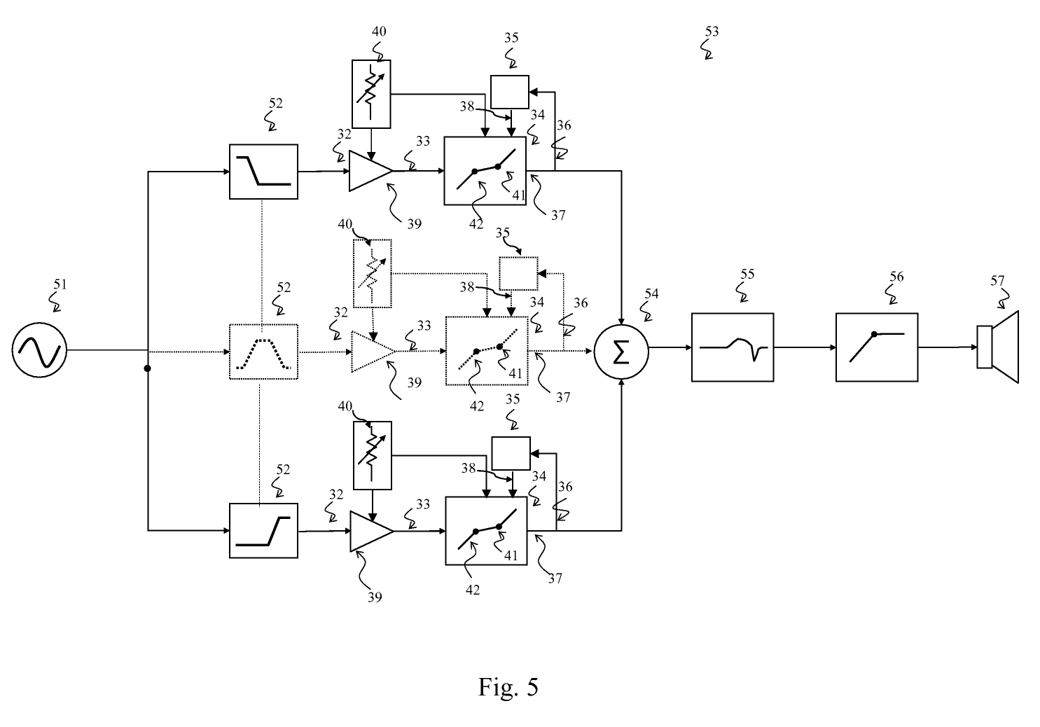

FIG. 5 is a block diagram of an apparatus 53 for amplification having a multiple frequency bands. The apparatus includes a signal source 51, band filters 52, band amplifiers 39, level detectors 35, band compressors 34, a signal combining device 54, an equalization filter 55, an output-limiting compression amplifier 56, and an output device 57. The signal source 51 may be a microphone, telephone line, a storage device, or wireless transmission. The storage device may be a record, a compact disk, an audio tape, a video tape, a digital video disk, a computer hard drive, a flash memory, and a read-only memory. The band filters 52 may be low pass, high pass, and/or band pass filters. The band amplifiers 39 may have a predetermined or user adjusted gain control 40 which may be in communication with the band compressor 34. Setting of the predetermined or user adjusted gain control 40 may select a predetermined input-output curve. The level detectors 35 sense the amplitudes of the output of the band amplifiers 39. The compressors 34 have a linear region below a sub-threshold 42 output level, a compression region below a predetermined threshold 41 output level, and a linear region above the predetermined threshold 41 output level. The equalization filter 55 may fine-tune frequency response, compensate for deficiencies in frequency response of the output device 57, and/or achieving a diffuse field reference. The output device 57 may be an earphone, a telephone receiver, a hearing aid receiver, or a speaker. The output device 57 may correct the frequency response of the output signal to achieve a diffuse-field equivalent response.

A sound signal enters the system at 51. The sound signal may be a broadband signal, and the broadband signal may be divided into low-, mid-, and/or high-frequency band channels by band filters, 52. The number, width, and spectral location of the bands may be a design decision for a specific implementation. Preferably, the slopes and off-band characteristics of the band filters are such that, once the bands have been amplified by differing amounts, the bands will recombine at 54 into a single signal whose frequency response is free from anomalous shapes or discontinuities.

The apparatus may be implemented in hardware or in software, such as in a digital signal processor, hereafter referred to as a processor. The processor may implement rules which may perform the same functions as the amplifiers 39, level detectors 35 and band compressors 34. Predetermined or user adjustable maximum gains of the band amplifiers 39 may be selected according to auditory needs of a listener. An output level of the band compressor 34 may be detected by a level detector 35. This level detector 35 determines where, in relation to thresholds 42 and 41, the output level lies, and therefore whether changes in signal amplitude around the detected value shall be compressed or passed through in a linear fashion by band compressors 34.

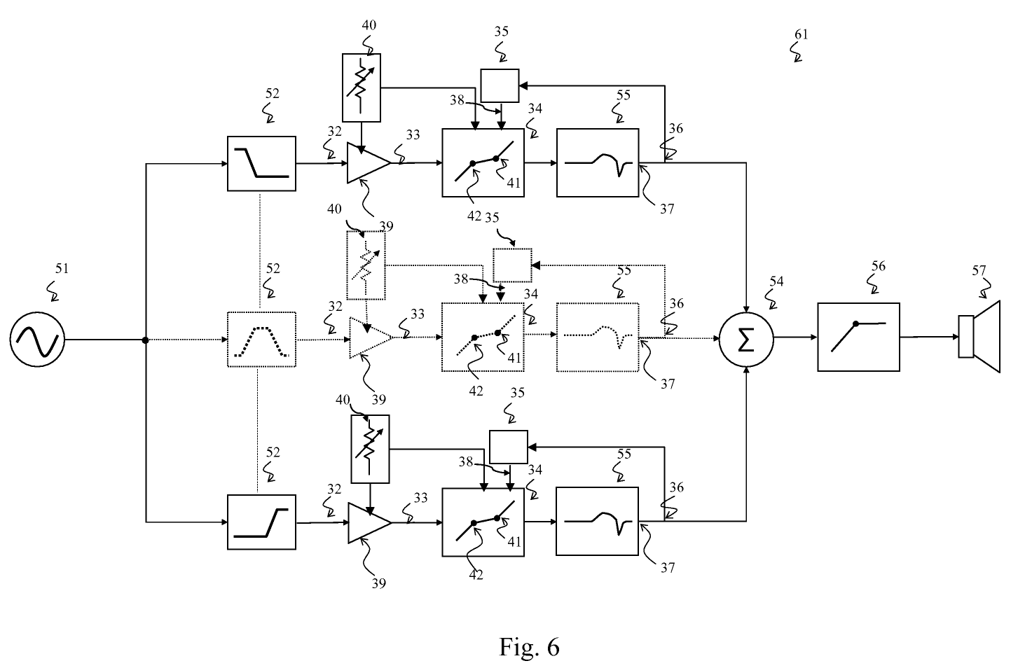

FIG. 6 is a block diagram of an apparatus 61 for amplification having a multiple equalization filters 55. The apparatus includes a signal source 51, band filters 52, band amplifiers 39, level detectors 35, band compressors 34, a signal combining device 54, equalization filters 55, an output-limiting compression amplifier 56, and an output device 57. The equalization filters 55 are in communication with the output of the band compressors 34, and the level detectors 35 are in communication with an output of the band compressor through the equalization filters 55. This configuration may be advantageous as it allows the equalization filters to fine-tune frequency response, compensate for deficiencies in frequency response of the output device 57, and/or achieving a diffuse field reference while still maintaining the desired output characteristic of a compression ratio greater than one for output signals below a predetermined threshold 41 output level and essentially one for output signals above the predetermined threshold 41 output level.

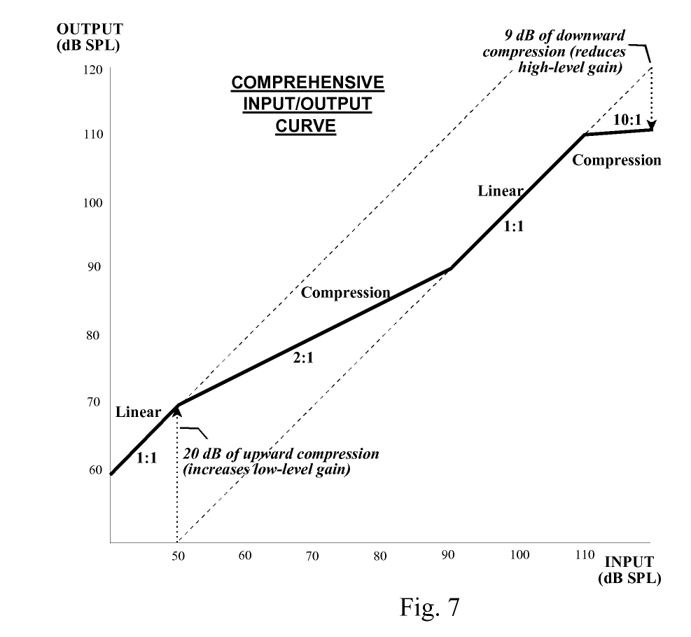

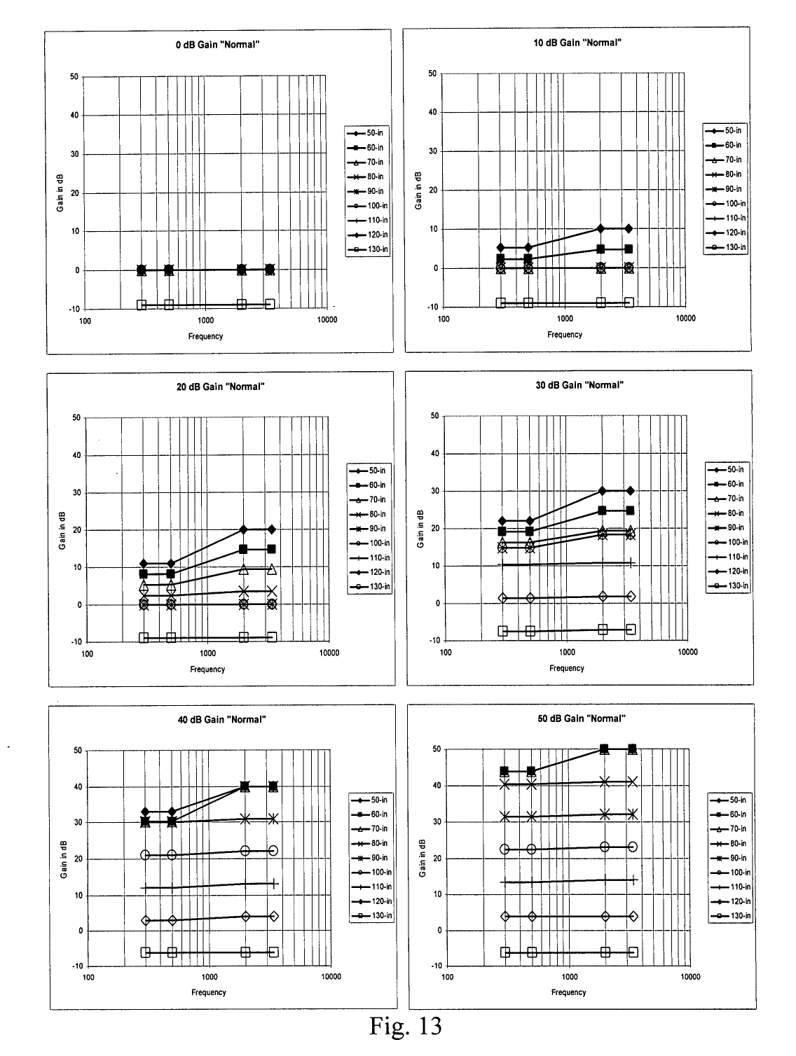

FIG. 7—FIG. 13 are examples of compression:

The dynamic range in FIG. 7 has regions of both upward compression and output-limiting compression, as well as regions without compression. In FIG. 7, an overall input range of 80 dB corresponds to an overall output range of 51 dB. It is said, therefore, that 29 dB of compression takes place over the specified input dynamic range. In the regions marked “Linear,” no compression takes place. The output grows at the same rate as the input; a unit change in the input gives a unit change in the output. In the regions marked “Compression,” the output grows more slowly than the input.

In the region of inputs between 50 and 90 dB SPL, the output grows only from 70 to 90 dB SPL; a 40 dB change in the input corresponds to only a 20 dB change in the output. It is said, therefore, that the “compression ratio” in this region is two-to-one (2:1). This is a region of “upward compression,” because its function is to raise the level of lower level inputs, in this case by a maximum of 20 dB for inputs of 50 dB SPL and below. In the region of inputs from 110 to 120 dB SPL, we see a compression ratio of about 10:1; for a 10-dB increase in the input level we have only a 1-dB increase in the output level. This application of downward compression is also called “output-limiting” compression, because the output level can grow only very slowly above 110 dB SPL. Between the two compression regions there is a region of linear processing, corresponding to the “loud but not uncomfortable” region of ear-canal sound-pressure levels for which the normal cochlea uses no compression action.

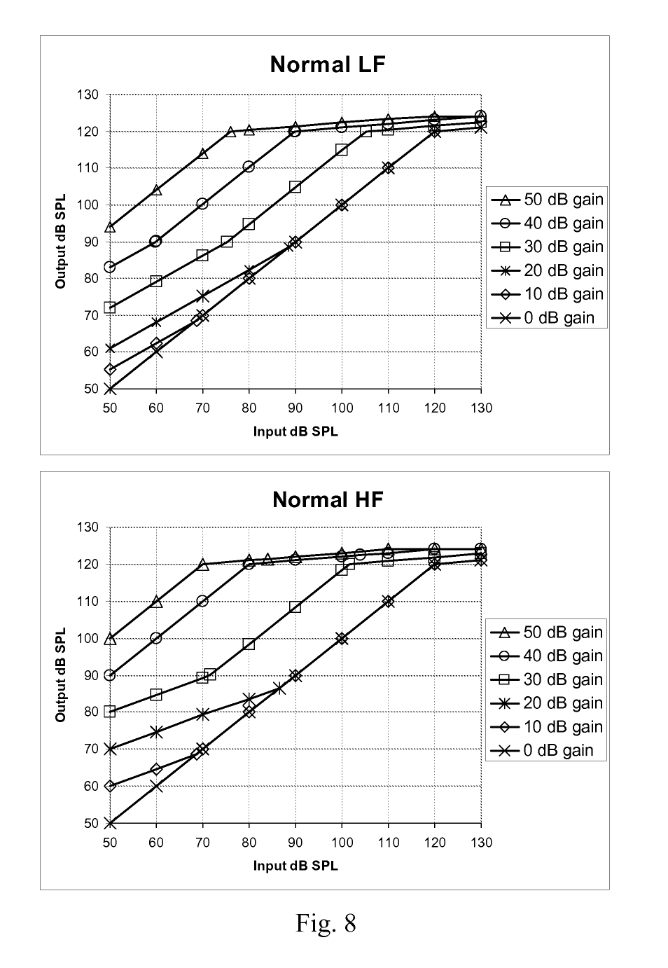

In the processor, there may be up to three kneepoints. In the example of FIG. 7, above, for outputs below 70 dB SPL (the first kneepoint), the processor is linear. For outputs between 70 and 90 dB SPL, the processor applies upward compression, independently in each band, unless doing so violates the other rules in the algorithm as will be discussed later. Where upward compression is allowed at outputs between 70 and 90 dB SPL, a second kneepoint occurs either at or slightly below an output of 90 dB SPL—above which the processing becomes linear, until the combined channel outputs reach the third kneepoint—for example, at an overall output of 110 dB SPL—where output-limiting compression takes control. The threshold of output-limiting is shown in the examples of FIGS. 8-13 to occur at 120 dB SPL. However, design considerations may require changing that kneepoint to other values in the final implementation of the processor.

Compression ratios of compressive regions in the low-, mid-, and high-band channels, where the band gain stage outputs are between 42 and 41, may also be selected according to needs of a listener, and may determine, for example, a degree of maximum high-frequency emphasis afforded the listener at lower signal levels, compared to that at higher signal levels. Greater high-frequency emphasis at lower signal levels is known as “TILL,” for “treble increases at low levels.

Following the band compressors 34, a combining device 54 may recombine the amplified band signals into a single broadband channel. A final equalization filter 55 may be used to fine-tune frequency response. This may be to compensate for deficiencies in frequency response of output device 57. Alternatively, an equalization filter 55 may follow each band compressor 34, after which the signals may be recombined by the combining device 54. Output device 57 may be an earphone receiver. The signal path of the amplifier may comprise a frequency-response correction to achieve a diffuse-field reference. Such a correction may be integral to the output device 57, or, if necessary, may be applied electronically so that, in concert with the output device 57, the diffuse-field reference is achieved. An output-limiting compressor 56 may assure that safe and comfortable listening levels are not exceeded and that the output does not exceed a maximum normal operating level of the device.

Applications:
Hearing Aids
Telephones (especially those to be used by hearing-impaired listeners, or by normal-hearing listeners in noisy environments)
Assistive listening devices—such as individually used FM receivers provided by venues such as churches and theaters.
Wireless personal communication devices, such as are now appearing on the market—whereby a hearing-impaired listener can receive wireless-transmitted signals from a single talker or multiple talkers
Other listening devices that require sound enhancement to compensate for adverse listening conditions

With the Amplification Method, the level detector is after the band compressor 34, and therefore the position of the signal relative to the thresholds on the I/O curve is determined by the band output, rather than the input. By controlling the I/O characteristic based on output, the new method controls a signal at the input to the ear (and ultimately the cochlea) for all possible settings of the band gains. For example, the cochlea may be compressive for signal levels below a certain level, about 90 dB SPL for example, and linear above that level. The typical implementation of the new method fixes the transition from compressive to linear processing at a desired output level (the device output being the input to the ear), for example at a 90 dB SPL output, for all settings of the system or band gain controls.

Example Implementation:

For example, there may be two band filters, creating high-pass and low-pass band channels. The characteristic of the low-pass filter may be such that the band gain begins to fall above 500 Hz and is 6 dB down at 1000 Hz. The characteristic of the high-pass filter may be such that the band gain begins to fall below 2000 Hz and is 6 dB down at 1000 Hz. Preferably, when the two bands have equal gain, the broadband frequency response of the recombined signal is flat.

A user operated gain (“Volume”) control may set the maximum gain of the high-frequency band amplifier 39. A “Tone” control may set the low-frequency band gain, or may set the ratio of high- to low-frequency band gains. The tone control may have the constraint that the total low-frequency band gain cannot exceed the total high-frequency band gain, and may also have the further constraint that the total low-frequency band gain cannot be more that 30 dB less than the total high-frequency band gain. Setting the “Tone” control may also determine compression ratios used in a compression region between 42 and 41 of the I/O-control component. The extremes of the “Tone” setting may be “Normal”—giving the flattest frequency response in the sub-42 linear region (i.e., where the maximum band gain is in effect at the input to the combining device)—and “Treble”—giving the greatest high-frequency emphasis to the frequency response in the sub-42 linear region (i.e., where the maximum band gain is in effect at the input to the combining device). When the “Tone” setting is at “Normal,” the low-frequency band gain may be set to equal that of the high-frequency band, the compression ratio (between 42 and 41) of the low-frequency band may be 1.4:1, and the compression ratio (between 42 and 41) of the high-frequency band may be 2.15:1. When the “Tone” setting is at “Treble,” the low-frequency band gain may be set to unity (except where the 30-dB constraint, as above, would be exceeded), the compression ratio (between 42 and 41) of the low-frequency band may be 1:1 (linear), and the compression ratio (between 42 and 41) of the high-frequency band may be 2.4:1. For “Tone” settings between “Normal” and “Treble,” band gains and compression ratios may be determined by linear interpolation (in decibels).

The amplifier may act prosthetically, to replace a natural “cochlear amplifier” that, when damaged or missing, is a common cause of mild-to-moderate hearing impairment. In this prosthetic capacity, a low-level compression action of the amplifier amplifies soft sounds, but leaves louder sounds unamplified. However, when a hearing impairment exceeds a moderate range, thus requiring some amplification of louder sounds, the amplifier adds an appropriate linear amplification while using output-limiting compression to protect against overload of both the ear and the circuitry. All compression kneepoints are output-referred (see later), so that what reaches the eardrum, not what enters the hearing instrument, determines the function of the compressors. Also, changing the maximum gain setting does not affect the output level at which processing changes from compressive to linear.

For mild-to-moderate hearing loss, the amplifier may serve in a prosthetic role, enhancing or replacing low-level compressive function of a damaged or missing OHC cochlear amplifier (the most common form of mild-to-moderate hearing loss). The amplifier may become linear for outputs of 90 dB SPL and above, for example, rather than for inputs of 90 dB SPL and above, for example. Thus, with the amplifier, the input level to the auditory system at which compression disappears may be consistent across all gain settings (within certain other minor constraints). For severe hearing losses involving damaged or missing IHCs, the amplifier provides appropriate linear gain for louder sounds, along with output-limiting compression to prevent overload distortion and uncomfortable levels. The output level for compressive-to-linear transition remains constant, corresponding to a constant auditory input level of 90 dB SPL, for example, regardless of other settings.

Detailed Description of the Processor:

A processor may consist of two main processing sections: a single- or multi-band, low-level compression section followed by a broadband, output-limiting section. The low-level compression section may have independent low-, mid-, and high-frequency sub-bands. In a two-band implementation, a low-frequency band may have flat frequency response below 500 Hz and a high-frequency band may have flat frequency response above 2000 Hz. The transition between the flat-response regions of each band may be a straight line connecting the 500- and 2000-Hz points on a linear-decibel-vs.-log-frequency scale. Other crossover frequencies and designs may be used.

In a two-band implementation, the 2-band sections may operate within stepped or continuous settings along two dimensions: “Volume” and “Tone.” Volume may refer to maximum low-level gain (for example, for 50 dB SPL and lower input levels) in the high-frequency band. The range of Volume settings may be 0 to 50 dB. The Tone dimension may vary compression ratios in both bands, effectively varying the amount of high-frequency emphasis (low-versus high-band gain). The range of Tone settings may be “Normal” to “Treble.” At the Normal (flatter) extreme, the low-frequency band compression ratio may be 1.4:1, while the high-frequency band compression ratio may be 2.15:1. At the Treble (high-frequency emphasis) extreme, the low-frequency band compression ratio may be 1:1 (no compression), while the high-frequency band compression ratio may be 2.4:1. The above compression ratios were derived from the work of Keidser and Grant (2001b), representing values that may be appropriate for a wide range of hearing impairments having flat to sloping configurations, although other compression ratios may also be used.

When the output of either sub-band reaches 90 dB SPL, for example, the dynamic processing in that band may become linear (1:1).

The outputs of the sub-band channels may be summed, and then may be subject to the broadband, output-limiting section of the processor. The broadband compression ratio may be approximately 10:1, and the threshold may be at 110 dB output SPL (or other, as desired). This feature may combine with software- and/or hardware-clippers to assure that uncomfortable loudness is never reached under normal operating conditions.

Other Rules:

The transition to linear processing may occur for outputs other than 90 dB SPL, for example, subject to the following rules, which supersede the processing rules described above. First, the gain of the low-frequency band may never be permitted to exceed the gain of the high-frequency band. Such is standard practice for accommodating flat to sloping hearing losses where low-frequency energy can mask high-frequency sounds to a greater extent than in normal-hearing ears. Second, the difference between the gains in the low- and high-frequency bands may never be permitted to exceed 30 dB. Skinner and Miller (1983) showed that intelligibility decreases with low-to-high-frequency gain differentials greater than 33 dB, even though a steeply sloping hearing loss configuration may seem to call for greater differentials.

Example Curves:

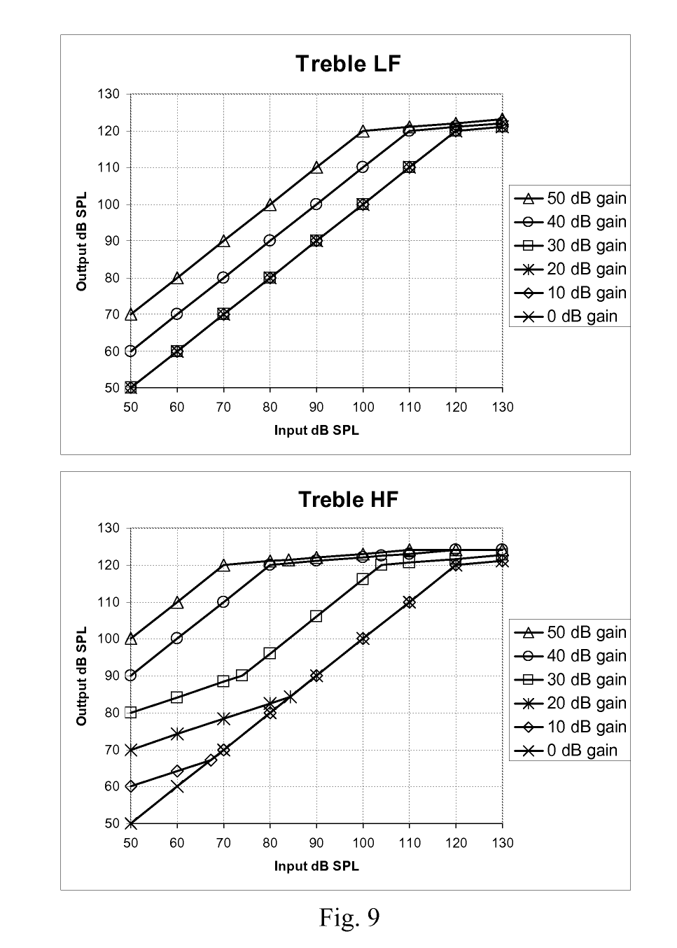

FIG. 8 through FIG. 13 are example sets of curves describing the functioning of the amplifier. The particular values in this description are as implemented in a telephone system by a telephone manufacturer; however, the actual numbers of Volume and Tone settings may be changed, leading to different numbers of possible I/O and frequency response curves. In FIG. 8 and FIG. 9 are shown input/output (I/O) curves, which are samples of the numerous possible low-frequency and high-frequency (LF and HF) I/O pairs in this implementation. Only a sample of curves at the Normal (FIG. 8) and Treble (FIG. 9) extremes is shown. The curves not shown may be interpolated across numerous possible Volume (gain) settings, such as between 0 and 50 dB, and numerous possible Tone settings per Volume setting, between Normal and Treble. The number of Tone settings may be chosen to increase as the Volume setting increases.

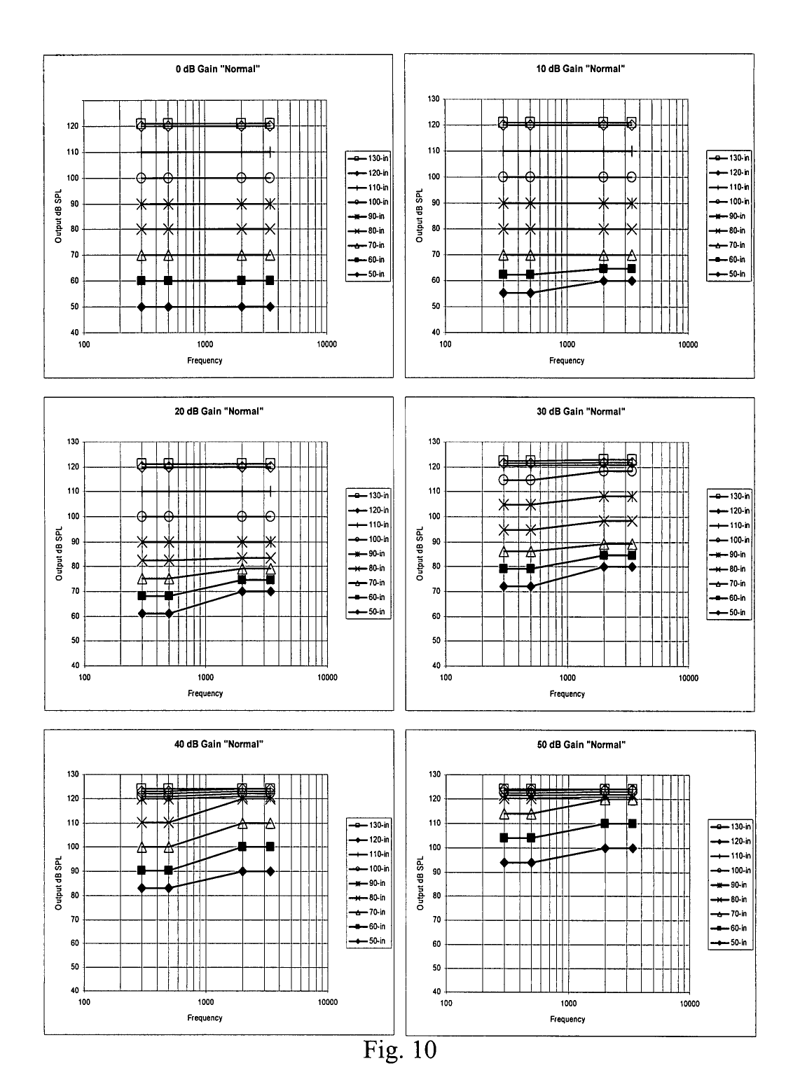

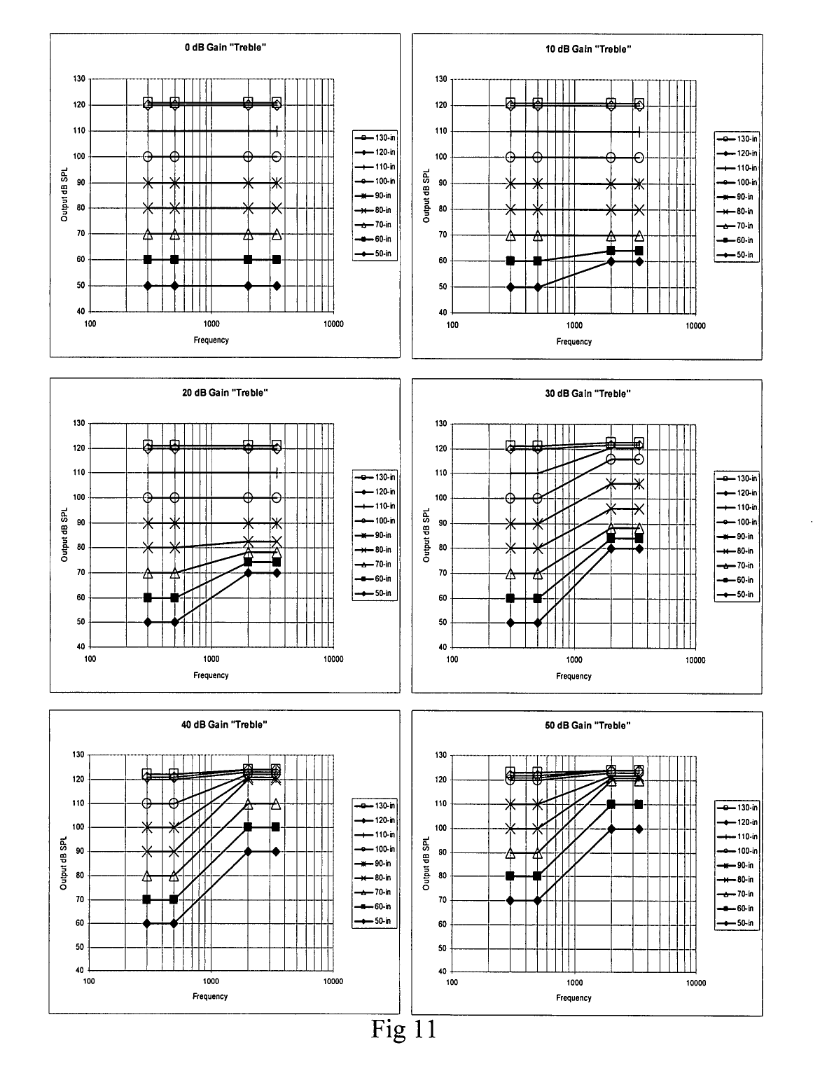

In FIG. 10 and FIG. 11 are shown output versus frequency response curves for the extremes of the Normal versus Treble tone range. These are a partial sampling of the thousands of possible interpolated curves, occurring as may be determined by the preset I/O functions and the instantaneous input signals. The actual number of possible frequency response curves may be limited by the amplitude resolution and memory of a digital signal processing platform used to implement the amplifier.

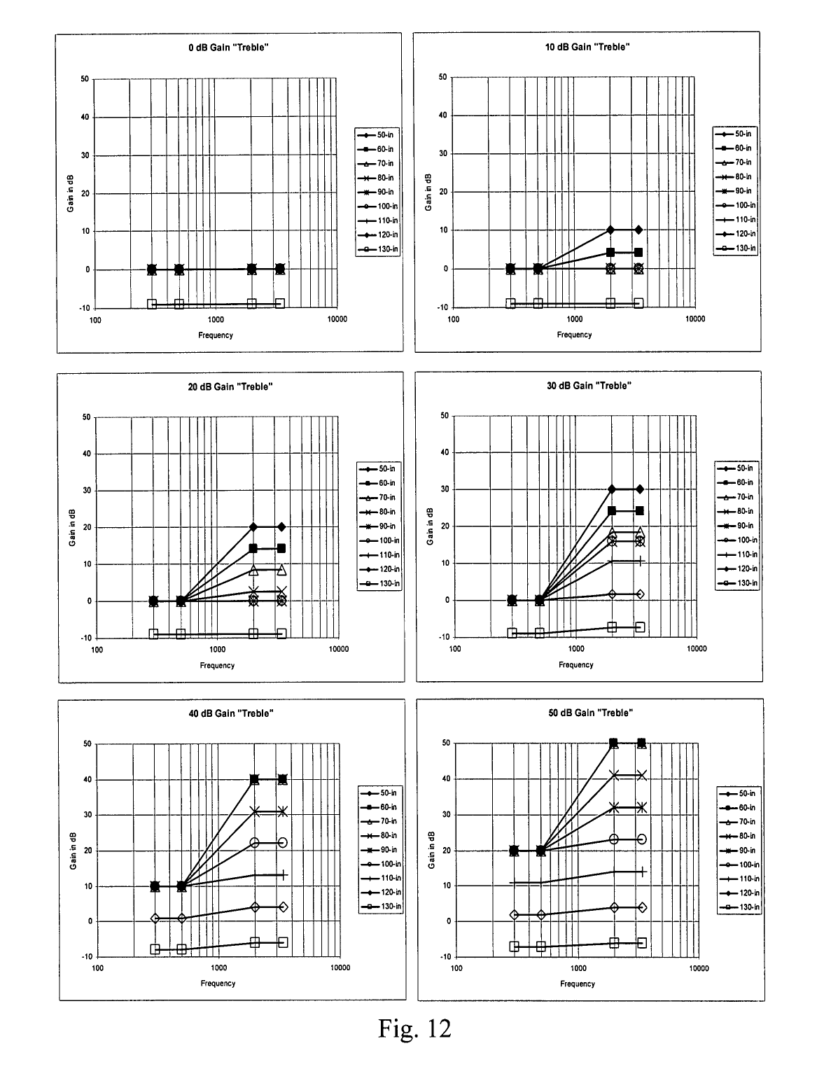

In FIG. 12 and FIG. 13 are a set of curves for gain versus frequency response, offering an alternate perspective on the same process seen in FIG. 10 and FIG. 11.

What is claimed:

1. A method of amplification comprising:
amplifying an input signal with a predetermined or user adjustable maximum gain to produce a second signal;
compressing the dynamic range of the second signal with an automatic gain control to produce an output signal;
wherein the compression ratio of the automatic gain control is greater than one for output signals below a predetermined threshold output signal level and is essentially one for output signals above the predetermined threshold output signal level.

2. The method of claim 1 wherein the compression ratio is predetermined.

3. The method of claim 1 further comprising one or more steps selected from the group consisting of determining the compression ratio of the automatic gain control, altering the compression ratio below one or more sub-thresholds, altering the compression ratio above a maximum threshold, eliminating noise, dividing the input signal into low- mid- and/or high-frequency band channels, recombining amplified band signals into a single broadband channel, fine-tuning frequency response, compensating for deficiencies in frequency response of an output device, achieving a diffuse-field equivalent response, correcting the frequency response of the output signal to achieve a diffuse-field equivalent response, assuring safe listening levels, assuring comfortable listening levels, and assuring output does not exceed a maximum normal operating level.

4. The method of claim 3 wherein the compression ratio is determined according to one of the amplitude of the output signal or an input-output curve.

5. The method of claim 4 wherein the input-output curve is one of predetermined, selected according to the auditory needs of a listener, and determined according to the predetermined or user adjustable maximum gain.

6. The method of claim 5 wherein at least one of the output signal level for which the input-output curve changes from compressive to linear and the function of the automatic gain control is not affected by the setting of the user adjusted or predetermined maximum gain.

7. The method of claim 1 wherein the compression ratio varies according to frequency.

8. The method of claim 7 wherein the compression ratio increases or decreases as frequency increases.

9. The method of claim 1 wherein at least one of the compression ratio, the predetermined threshold output level, and the predetermined or user adjustable maximum gain is selected according to the auditory needs of a listener.

10. The method of claim 1 wherein the predetermined threshold output signal is one of a specified level or 90 dB SPL.

11. An apparatus comprising:
A band amplifier comprising a predetermined or user adjustable maximum gain control, an input, and an output;
a band compressor in communication with the output of the band amplifier;
and a level detector comprising an input in communication with an output of the band compressor and further comprising an output in communication with the band compressor.
wherein the band compressor has a compression ratio greater than one for output signals below a predetermined threshold output level and is essentially one for output signals above the predetermined threshold output level.

12. The apparatus of claim 11 wherein at least one of the compression ratio, the predetermined threshold output level, and a gain of the band amplifier is selected according to the auditory needs of a listener.

13. The apparatus of claim 11 comprising one or more devices selected from the group consisting of a signal source, a band filter, a signal combining device, an equalization filter, an output-limiting compression amplifier and an output device.

14. The apparatus of claim 13 wherein the signal source is selected from the group consisting of a microphone, a telephone line, a storage device, and a wireless receiver.

15. The apparatus of claim 14 wherein the storage device is selected from the group consisting of a record, a compact disk, an audio tape, a video tape, a digital video disk, a computer hard drive, a flash memory, and a read-only memory.

16. The apparatus of claim 13 wherein the band filter is selected from the group consisting of low pass, high pass, and band pass filters.

17. The apparatus of claim 13 wherein the equalization filter performs one or more functions selected from the group consisting of fine-tuning frequency response, compensating for deficiencies in frequency response of an output device, and achieving a diffuse field reference.

18. The apparatus of claim 13 wherein the output device is selected from the group consisting of an earphone, a telephone receiver, a hearing aid receiver, and a speaker.

19. The apparatus of claim 13 wherein the output device corrects the frequency response of the output signal to achieve a diffuse-field equivalent response.

20. The apparatus of claim 13 wherein the output-limiting compressor assures that the output does not exceed one or more levels selected from the group consisting of safe listening levels, comfortable listening levels, and maximum operating levels.

21. The apparatus of claim 11 further comprising one or more additional amplifiers, each amplifier comprising a band amplifier comprising a predetermined or user adjustable gain control, an input and an output, a band compressor connected to the output of the band amplifier, and a level detector comprising an input in communication with the output of the band compressor and further comprising an output in communication with the band compressor. Wherein the band compressor has a compression ratio greater than one below a predetermined threshold output level and essentially one above the predetermined threshold output level.

22. The apparatus of claim 21 comprising multiple band filters wherein slopes and off-band characteristics of the band filters are such that, once the bands have been amplified by differing amounts, the bands will recombine into a single signal whose frequency response is free from anomalous shapes and discontinuities.

23. The apparatus of claim 11 wherein the predetermined or user adjustable gain control is in communication with the band compressor and/or determines the input-output curve of the band compressor.
